(19) United States
(12) Patent Application Publication
(10) Pub. No.: US 2013/0008492 A1
(43) Pub. Date: Jan. 10, 2013

(54) POROUS FILM TYPE SOLID ELECTROLYTE, DYE-SENSITIZED SOLAR CELL USING THE SAME, AND MANUFACTURING METHOD THEREOF

(75) Inventors: Yong Jun Jang, Seongnam (KR); Sang Hak Kim, Seoul (KR); Won Jung Kim, Seoul (KR); Yong Gu Kim, Hwaseong (KR); Mi Yeon Song, Seoul (KR); In Woo Song, Hwaseong (KR); Ji Yong Lee, Hwaseong (KR); Ki Chun Lee, Seoul (KR)

(73) Assignee: HYUNDAI MOTOR COMPANY, Seoul (KR)

(21) Appl. No.: 13/251,683

(22) Filed: Oct. 3, 2011

(30) Foreign Application Priority Data
Jul. 8, 2011 (KR) 10-2011-0068133

(51) Int. Cl. H01L 31/02; H01L 31/0224; C09K 3/00

(52) U.S. Cl. 136/252; 252/62.2; 438/98; 257/E31.124

(57) ABSTRACT

Disclosed is a porous film type solid electrolyte, a dye-sensitized solar cell using the same, a method for manufacturing the same. More particularly, a porous film type solid electrolyte for improving long-term durability of a dye-sensitized solar cell is disclosed. The disclosure provides a porous film type solid electrolyte prepared by impregnating an electrolyte material into a porous polymer film formed from a film composition comprising 0.1-90 wt % of a UV-curable polymer material, 0.1-10 wt % of a nonionic emulsifier and 0.01-0.1 wt % of a photocrosslinking initiator.

### CROSS-REFERENCE TO RELATED APPLICATIONS

This application claims priority under 35 U.S.C. §119 to Korean Patent Application No. 10-2011-0068133, filed on Jul. 8, 2011, in the Korean Intellectual Property Office, the disclosure of which is incorporated herein by reference in its entirety.

### BACKGROUND

(a) Technical Field

The present invention relates to a porous film type solid electrolyte, a dye-sensitized solar cell using the same, a method for manufacturing the same. More particularly, the present invention relates to a porous film type solid electrolyte for improving long-term durability of a dye-sensitized solar cell.

(b) Background Art

As the global warming becomes a more serious issue, there is a growing concern on the development of technologies utilizing clean energy. In particular, solar cells utilizing renewable energy source have been found to be very beneficial. Currently available solar cells include silicon-based solar cells, thin-film solar cells using inorganic materials such as copper indium gallium selenide (CIGS; Cu(InGa)Se₂), dye-sensitized solar cells, organic solar cells, and organic-inorganic hybrid solar cells. Among them, the dye-sensitized solar cell, which is inexpensive and commercially efficient, is valued highly not only in the building-integrated photovoltaics (BIPV) industry but also in the mobile electronics industry.

Differently from other solar cells, the dye-sensitized solar cell is capable of absorbing visible light and producing electricity by the photoelectric conversion mechanism. In general, a dye-sensitized solar cell uses liquid electrolyte or gel-type polymer electrolyte (gel electrolyte). The liquid or gel-type electrolyte, however, often leaks out when the substrate or enclosure of the solar cell is broken, resulting in degradation of durability and product quality and related health problems.

To solve this problem, development of a solid electrolyte has been actively carried out. In general, a solid electrolyte is formed by attaching the electrolyte component on the surface of a photoelectrode (or working electrode, typically made of TiO₂) of the dye-sensitized solar cell by deposition or spin coating and completely drying the solvent included in the attached electrolyte component. When such solid electrolyte is used, however, it is difficult to expect suitable power generation efficiency because the current density is very low.

Also, although the technique of forming a solid electrolyte with a porous structure by electrospinning to improve the power generation efficiency of a solar cell is known, it requires high initial investment cost and the polymer materials that can be used as the electrolyte component are restricted.

### SUMMARY

The present invention is directed to providing a film type solid electrolyte having a porous structure prepared using a nonionic emulsifier having a low flash point and a UV-curable polymer material to increase the impregnation amount of electrolyte, in order to solve the leakage and long-term stability problems of liquid electrolyte used in the existing liquid dye-sensitized solar cell.

In particular, the present invention is also directed to providing a dye-sensitized solar cell using the solid electrolyte, which can be manufactured by a simple process and is capable of improving energy conversion efficiency, and a method for manufacturing the same. In one general aspect, the present invention provides a porous film type solid electrolyte prepared by impregnating an electrolyte material into a porous polymer film formed from a film composition comprising 0.1-90 wt % of a UV-curable polymer material, 0.1-10 wt % of a nonionic emulsifier and 0.01-0.1 wt % of a photocrosslinking initiator.

Specifically, the UV-curable polymer material may be one or more selected from the group consisting of polyacrylonitrile, polyacrylate, polymethacrylate, poly(methyl methacrylate) and polyvinyl alcohol. The nonionic emulsifier may be polyoxyethylene nonylphenol ether, specifically polyoxyethylene nonylphenol ether with the number of oxyethylene repeat units n being an integer from 1 to 60. The UV-curable polymer material may have a weight-average molecular weight from about 300 to 20,000, and the porous polymer film may have pores with a size of about 1-200 μm. In another general aspect, the present invention provides a dye-sensitized solar cell having the porous film type solid electrolyte.

In another general aspect, the present invention provides a method for manufacturing a dye-sensitized solar cell, including: forming a working electrode on a first substrate on which a transparent conductive layer is coated; laminating on the working electrode the porous film type solid electrolyte described above; forming a counter electrode on a second substrate on which a transparent coating layer is coated; and laminating the second substrate on the solid electrolyte such that it contacts the counter electrode, and bonding and immobilizing the first substrate and the second substrate with a sealing agent.

The above and other aspects and features of the present invention will be described infra.

### BRIEF DESCRIPTION OF THE DRAWINGS

The above and other objects, features and advantages of the present invention will now be described in detail with reference to certain exemplary embodiments thereof illustrated in the accompanying drawings which are given hereinbelow by way of illustration only, and thus are not limitative of the invention, and wherein:

FIG. 1 shows the cross-section of a dye-sensitized solar cell according to an embodiment of the present invention; and

FIG. 2 is an enlarged image of a porous polymer film of a solid electrolyte for a dye-sensitized solar cell according to an embodiment of the present invention.

### DETAILED DESCRIPTION OF MAIN ELEMENTS

101: first substrate
102: sealing agent
103: working electrode (inorganic oxide layer)
104: solid electrolyte (porous film type solid electrolyte)
105: counter electrode
106: second substrate

It should be understood that the appended drawings are not necessarily to scale, presenting a somewhat simplified representation of various preferred features illustrative of the basic principles of the invention. The specific design features of the invention as disclosed herein, including, for example, specific dimensions, orientations, locations and shapes, will be determined in part by the particular intended application and use environment.

### DETAILED DESCRIPTION

Hereinafter, reference will now be made in detail to various embodiments of the present invention, examples of which are illustrated in the accompanying drawings and described below. While the invention will be described in conjunction with exemplary embodiments, it will be understood that the present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

The present invention provides a solid electrolyte comprising a porous polymer film for a dye-sensitized solar cell, a dye-sensitized solar cell using the same, and a method for manufacturing the same. A film composition of a specific composition is used to prepare a polymer film with a porous structure in order to increase the impregnation amount of the electrolyte.

Specifically, the film composition for preparing the porous polymer film includes a UV-curable polymer material in the form of a nanofiber with an increased specific surface area for effectively inducing the increase of photocurrent, and a nonionic emulsifier with a decreased flash point for forming the porous structure of the polymer film to increase the impregnation amount of the electrolyte.

The nonionic emulsifier serves to form micelles capable inducing the porous structure in a polymer matrix of the film composition mixed together. As a result, the porous structure can be formed in the polymer film through a simple vacuum drying process. Accordingly, the film composition allows control of porosity of the polymer film through adjustment of the content of the nonionic emulsifier, and thus allows the impregnation amount of the electrolyte in the polymer film.

The porosity control through the adjustment of the content of the nonionic emulsifier is advantageous in that the control of the porosity of the polymer film is easier and simpler compared to the existing electrospinning process. Further, since the nonionic emulsifier does not react with the electrolyte and thus has no effect on the electrochemical reaction of the dye-sensitized solar cell, the reaction stability of the dye-sensitized solar cell is ensured.

Specifically, the film composition comprising nonionic emulsifier includes a mixture of about 0.1-90 wt % of a UV-curable polymer material, about 0.1-10 wt % of a nonionic emulsifier, and about 0.01-0.1 wt % of a photocrosslinking initiator. When the content of the UV-curable polymer material in the film composition is less than about 0.1 wt %, it will be difficult to maintain the form of a film. In contrast, if it exceeds 90 wt %, formation of the porous structure will be difficult. The UV-curable polymer material may be a polymeric monomer mixture that can be cured by UV radiation. Specifically, one or more selected from the group consisting of polyacrylonitrile, polyacrylate, polymethacrylate, poly(methyl methacrylate) and polyvinyl alcohol may be used.

The nonionic emulsifier is mixed in the film composition in the aforesaid amount to form micelles. When the content of the nonionic emulsifier is less than about 0.1 wt %, it will be difficult to form the porous structure in the polymer film. In contrast, if it exceeds about 10 wt %, it will be difficult to maintain the form of the film (formed from the film composition) because of too high porosity. The nonionic emulsifier may be polyoxyethylene nonylphenol ether, particularly polyoxyethylene nonylphenol ether with the number of oxyethylene repeat units n being from 1 to 60.

The photocrosslinking initiator is included in the aforesaid amount, and serves to initiate the immobilization of the UV-curable polymer material and the nonionic emulsifier via photocrosslinking. Specifically, the UV-curable polymer material may have a weight-average molecular weight from about 300 to 20,000. When the weight-average molecular weight is smaller than about 300, the film composition may not form a film. In contrast, if the weight-average molecular weight exceeds about 20,000, it will be difficult to form the porous structure of the polymer film. The porous polymer film prepared using the film composition has pores with a size of about 1-200 μm.

Now, the process of preparing the porous film type solid electrolyte using the film composition will be described.

As described above, a UV-curable polymer material, a nonionic emulsifier and a photocrosslinking initiator are mixed to obtain a film composition, and the film composition is coated thinly on a substrate in the form of a film and cured by irradiating UV. Then, by inducing formation of a porous structure through vacuum drying, a porous polymer film with a number of pores is prepared. The UV-curable polymer material may be a polymer mixture comprising two or more of the aforesaid materials.

Subsequently, the porous polymer film is immersed in an electrolyte material, so that the electrolyte component is impregnated into the porous polymer film. As a result, a solid electrolyte for a dye-sensitized solar cell is obtained. Since the electrolyte is impregnated into the pores of the porous polymer film, the electrolyte impregnation ratio is higher than that of the existing non-porous structure solid electrolyte.

Now, the configuration and manufacturing process of a dye-sensitized solar cell using the porous film type solid electrolyte will be described.

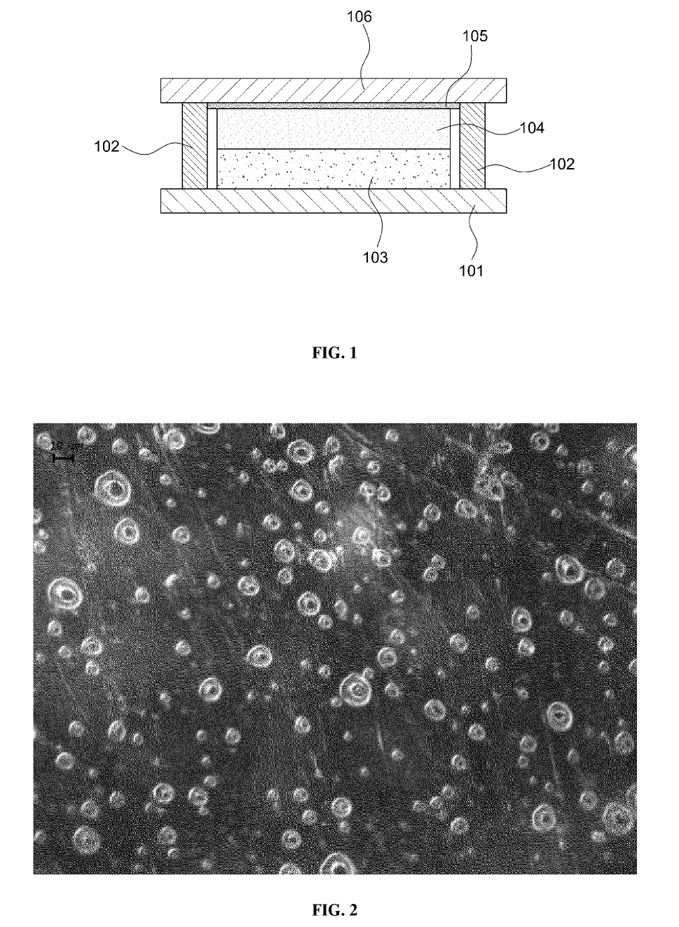

FIG. 1 shows the cross-section of a dye-sensitized solar cell manufactured using a porous film type solid electrolyte according to an embodiment of the present invention, and FIG. 2 is an enlarged image of a porous polymer film of a solid electrolyte for a dye-sensitized solar cell according to an embodiment of the present invention.

To manufacture a dye-sensitized solar cell with the configuration shown in FIG. 1, an inorganic oxide (e.g., titanium dioxide) is coated using a screen printing apparatus on a first substrate 101 on which a transparent conductive layer is coated to form an inorganic oxide layer. Then, after heating at a predetermined temperature for a predetermined time, the resultant is cured at a predetermined temperature for a predetermined time to form a working electrode 103. After adsorbing a dye to the working electrode 103 at room temperature, the porous film type solid electrolyte is laminated on the dye-adsorbed working electrode.

After forming a counter electrode 105 using a platinum material on a second substrate 106 on which a transparent coating layer is coated, the second substrate 106 is laminated on the porous film type solid electrolyte 104 such that it contacts the counter electrode 105, and the first substrate 101 and the second substrate 106 are bonded and immobilized using a sealing agent 102, so that the porous film type solid electrolyte 104 is immobilized between the counter electrode 105 and the working electrode 103.

As shown in FIG. 1, in thus manufactured dye-sensitized solar cell, the working electrode 103 (inorganic oxide layer) is formed on the first substrate 101, the counter electrode 105 is formed on the second substrate 106, and the porous film type solid electrolyte 104 is disposed between the counter electrode 105 and the working electrode 103. The sealing agent 102 is applied at both sides of the electrodes 103, 105 disposed between the first substrate 101 and the second substrate 106 to seal and immobilize them. The porous film type solid electrolyte 104 is disposed between the counter electrode 105 and the working electrode 103 and serves to effectively prevent short-circuit caused by contact.

The dye-sensitized solar cell according to the present invention reduces or prevents leakage of the electrolyte solvent and consequent degradation of durability that may occur due to damage to the sealing agent when the existing liquid electrolyte is used in the dye-sensitized solar cell. Accordingly, it is capable of simplifying and making economical the manufacturing process of the dye-sensitized solar cell.

When the porous film type solid electrolyte of the present invention is used as an electrolyte of the dye-sensitized solar cell, superior current density and photovoltaic efficiency is achieved since the impregnation amount of electrolyte is increased as compared to the existing non-porous film type solid electrolyte. Accordingly, a dye-sensitized solar cell with improved energy conversion efficiency can be provided.

### EXAMPLES

The electrochemical properties of dye-sensitized solar cells prepared according to examples and comparative examples will now be described. The following examples and experiments are for illustrative purposes only and not intended to limit the scope of this invention.

### Example 1

### Preparation of Porous Polymer Film

For preparation of a polymer solution, 79.9 wt % of polypropylene glycol monoacrylate, 10 wt % of polypropylene glycol diacrylate, 0.1 wt % of a photocrosslinking initiator and 10 wt % of polyoxyethylene nonyl phenyl ether were mixed, stirred for 24 hours, and coated thinly on a glass substrate. Subsequently, the polymer solution coated on the glass substrate was cured by irradiating UV (1,000 mJ) and dried in vacuum to prepare a porous polymer film having a number of pores.

### Example 2

### Preparation of Dye-Sensitized Solar Cell Using Porous Polymer Film of Example 1

A titanium dioxide paste for screen printing (Solaronix) was coated using a screen printing apparatus on the glass substrate on which fluorine-doped tin oxide (FTO) is coated. Then, a working electrode was formed by heating at 300° C. for 1 hour and baking at 500° C. for 3 hours. A dye (N3, Solaronix) was adsorbed to the formed working electrode for 24 hours at room temperature.

Subsequently, the porous polymer film of Example 1 was immersed in an electrolyte (AN 50, Solaronix) for 12 hours and, after placing the porous polymer film impregnated with the electrolyte on the dye-adsorbed working electrode, the substrate on which the counter electrode was formed by platinum coating was bonded at 120° C. to the glass substrate having the working electrode using Surlyn (DuPont).

### Comparative Example 1

### Preparation of Non-Porous Polymer Film

For preparation of a polymer solution, 89.9 wt % of polypropylene glycol monoacrylate, 10 wt % of polypropylene glycol diacrylate and 0.1 wt % of a photocrosslinking initiator were mixed, stirred for 24 hours, and coated thinly on a glass substrate. Subsequently, the polymer solution coated on the glass substrate was cured by irradiating UV (1,000 mJ) and dried in vacuum to prepare a non-porous polymer film.

### Comparative Example 2

### Preparation of Dye-Sensitized Solar Cell Using Non-Porous Polymer Film of Comparative Example 1

A titanium dioxide paste for screen printing (Solaronix) was coated using a screen printing apparatus on the glass substrate on which fluorine-doped tin oxide (FTO) is coated. Then, a working electrode was formed by heating at 300° C. for 1 hour and baking at 500° C. for 3 hours. A dye (N3, Solaronix) was adsorbed to the formed working electrode for 24 hours at room temperature.

Subsequently, the non-porous polymer film of Comparative Example 1 was immersed in an electrolyte (AN 50, Solaronix) for 12 hours and, after placing the non-porous polymer film impregnated with the electrolyte on the dye-adsorbed working electrode, the substrate on which the counter electrode was formed by platinum coating was bonded at 120° C. to the glass substrate having the working electrode using Surlyn (DuPont).

Electrochemical properties of the dye-sensitized solar cells prepared through Examples 1-2 and Comparative Examples 1-2 are described in Table 1.

TABLE 1

| | Current | Voltage | Fill | Energy conversion |
|---|---|---|---|---|
| | density (J_{sc}) | (V_{oc}) | factor (FF) | efficiency (%) |
| Ex. 1-2 | 3.743 | 0.557 | 31.5 | 0.65 |
| Comp. Ex. 1-2 | 0.037 | 0.613 | 22.0 | 0.005 |

As seen from Table 1, the dye-sensitized solar cell prepared using the porous polymer film of the present invention exhibited significantly improved current density and energy conversion efficiency as compared to the dye-sensitized solar cell prepared using the non-porous polymer film.

When the film type solid electrolyte with a porous structure according to the present invention is used for a dye-sensitized solar cell, the manufacturing process is simplified as compared to the dye-sensitized solar cell using liquid electrolyte since the preparation and sealing of the electrolyte injection portion are unnecessary. In addition, energy conversion efficiency is improved remarkably as compared to the dye-sensitized solar cell using the existing non-porous solid electrolyte.

The present invention has been described in detail with reference to specific embodiments thereof. However, it will be appreciated by those skilled in the art that various changes and modifications may be made in these embodiments without departing from the principles and spirit of the invention, the scope of which is defined in the appended claims and their equivalents.

What is claimed is:

1. A porous film type solid electrolyte prepared by impregnating an electrolyte material into a porous polymer film formed from a film composition comprising 0.1-90 wt % of a UV-curable polymer material, 0.1-10 wt % of a nonionic emulsifier and 0.01-0.1 wt % of a photocrosslinking initiator.

2. The porous film type solid electrolyte according to claim 1, wherein the UV-curable polymer material is one or more selected from the group consisting of polyacrylonitrile, polyacrylate, polymethacrylate, poly(methyl methacrylate) and polyvinyl alcohol.

3. The porous film type solid electrolyte according to claim 1, wherein the nonionic emulsifier is polyoxyethylene nonylphenol ether.

4. The porous film type solid electrolyte according to claim 1, wherein the nonionic emulsifier is polyoxyethylene nonylphenol ether with the number of oxyethylene repeat units n, wherein n is an integer from 1 to 60.

5. The porous film type solid electrolyte according to claim 1, wherein the UV-curable polymer material has a weight-average molecular weight from about 300 to 20,000.

6. The porous film type solid electrolyte according to claim 1, wherein the porous polymer film has pores with a size of about 1-200 μm.

7. A dye-sensitized solar cell comprising a porous film type solid electrolyte prepared by impregnating an electrolyte material into a porous polymer film formed from a film composition including 0.1-90 wt % of a UV-curable polymer material, 0.1-10 wt % of a nonionic emulsifier and 0.01-0.1 wt % of a photocrosslinking initiator.

8. A method for manufacturing a dye-sensitized solar cell, comprising:
forming a working electrode on a first substrate on which a transparent conductive layer is coated;
laminating on the working electrode the porous film type solid electrolyte by impregnating an electrolyte material into a porous polymer film formed from a film composition comprising 0.1-90 wt % of a UV-curable polymer material, 0.1-10 wt % of a nonionic emulsifier and 0.01-0.1 wt % of a photocrosslinking initiator;
forming a counter electrode on a second substrate on which a transparent coating layer is coated; and
laminating the second substrate on the solid electrolyte such that it contacts the counter electrode, and bonding and immobilizing the first substrate and the second substrate with a sealing agent.
